(19) United States
(12) Patent Application Publication
(10) Pub. No.: US 2018/0134544 A1
(43) Pub. Date: May 17, 2018

(54) TEMPERATURE COMPENSATION FOR RESONANT MEMS

(71) Applicant: CAMBRIDGE ENTERPRISE LIMITED, CAMBRIDGE CAMBRIDGESHIRE (GB)

(72) Inventors: ASHWIN SESHIA, CAMBRIDGE CAMBRIDGESHIRE (GB); CUONG DO, HANOI (VN)

(21) Appl. No.: 15/574,237

(22) PCT Filed: May 9, 2016
(86) PCT No.: PCT/GB2016/051316

§ 371 Date: Nov. 15, 2017

(30) Foreign Application Priority Data
May 15, 2015 (GB) 1508377.7

(51) Int. Cl. B81B 7/00; H03D 13/00

(52) U.S. Cl. CPC B81B 7/008; B81B 2201/0242; B81B 2201/0235; H03D 13/003

(57) ABSTRACT

A temperature-compensated resonant MEMS device comprises a first and second oscillator circuits comprising a first and second resonant MEMS devices and providing a first and second oscillator outputs. One of the resonant MEMS devices is a temperature reference for the other. A level-sensitive mixer circuit has first and second inputs coupled to the first and second oscillator outputs and has a mixer output to provide a signal responsive to a level of the first and second oscillator outputs. The mixer output comprises sum and difference frequency components of the first and second oscillator outputs. A low-pass filter is coupled to the mixer output to attenuate the sum frequency component of the mixer output. An output coupled to an output of said low-pass filter provides a signal responsive to the difference frequency component.

### FIELD OF THE INVENTION

This invention relates to MEMS (micro-electro-mechanical systems) systems and in particular to sensors and to their associated circuitry.

### BACKGROUND TO THE INVENTION

Distributed wireless sensing is increasingly viewed as an important enabling technology for a range of applications such as structural health monitoring of large-scale built infrastructure and in environmental monitoring. These applications may ultimately require operation in remote, inaccessible locations over lifetimes of several decades where battery replacement is impractical or expensive. While wireless technologies have made enormous strides in recent years in addressing continuous power demands, much of this reduction in power is achieved by operating the node in a low-power or stand-by mode while the sensor itself may still need to be powered up to enable “event-triggered” wake-up modes for the rest of the node. This in turn places a significant constraint on the power demand of the sensors themselves.

Current structural health monitoring systems typically combine commercial off the shelf (COTS) sensors with generic platforms for sensing, power management and wireless telemetry. However these are typically physically large and have power consumptions in the range 10s to 100s of mW. In addition these devices are relatively noisy and insensitive. General background prior art is described in US2010/0154553 and Oh et al., “Enhanced sensitivity of a surface acoustic wave gyroscope using a progressive wave”, J. Micromech. Microeng., vol. 21 (2011) 075015.

Cutting edge research can do better—for example strain gauges with better than 1 microstrain resolution with a 20 KHz bandwidth have been achieved. Previous research in the MEMS group of one of the inventors has achieved still better results (see, for example J. E-Y. Lee, B. Bahreyni, and A. A. Seshia, “An axial strain modulated double-ended tuning fork electrometer”, Sensors and Actuators, Part A: Physical, Vol. 148, No. 2, pp. 395-400, December 2008; and L. Belsito, M. Ferri, F. Mancarella, A. Roncaglia, J. Yan, A. A. Seshia and K. Soga, “High resolution strain sensing on steel by silicon-on-insulator flexural resonators fabricated with chip-level vacuum packaging”, Proceedings of the 17^{th} International Conference on Solid-State Sensors, Actuators and Microsystems (Transducers 2013), Barcelona, Spain, Jun. 16-20, 2013).

Further improvements are, however, still desirable. More particularly it would be advantageous to be able to achieve, simultaneously, extremely low power consumption and very low noise in the context of a temperature-compensated system.

### SUMMARY OF THE INVENTION

According to the present invention there is therefore provided a temperature-compensated resonant MEMS device, comprising: a first oscillator circuit comprising a first resonant MEMS device and providing a first oscillator output; a second oscillator circuit comprising a second resonant MEMS device and providing a second oscillator output; wherein one of said first and second resonant MEMS devices is a temperature reference for the other of said first and second resonant MEMS devices; a level-sensitive mixer circuit having first and second inputs respectively coupled to said first and second oscillator outputs and having a mixer output to provide a signal responsive to a level of said first and second oscillator outputs, said mixer output comprising sum and difference frequency components of said first and second oscillator outputs; a low-pass filter coupled to said mixer output to attenuate said sum frequency component of said mixer output; and an output coupled to an output of said low-pass filter to provide a signal responsive to said difference frequency component.

As the skilled person will appreciate, temperature compensation can be achieved by providing a pair of MEMS devices, one of which is used as a sensor, and the other as a reference. It is particularly advantageous to operate these MEMS devices in a resonant mode as the inherent device power dissipation is then minimised. A temperature-compensated signal can be provided by comparing the resonant frequency of the first, sensor MEMS device with that of the second, reference MEMS device. However there is then a need to achieve this whilst meeting the twin constraints of very low power consumption and very low noise (high resolution) where, typically, these conflict.

Some preferred embodiments of the system employ a ‘square wave’ drive for the MEMS devices, although this is not essential and, for example, sine or triangle wave signals may also be used. Here where we refer to a square wave, this includes waveforms which do not have a 1:1 mark:space ratio, that is ‘square’ includes ‘rectangular’.

It is desirable to be able to achieve a low power, low noise measurement of the frequency difference between the two MEMS devices. This problem is considered in U.S. Pat. No. 4,683,437 which describes frequency subtractors for use with sensor circuitry, noting in the ‘Background’ section the problem of jitter in precision systems, and describing a solution. The same problem is considered in U.S. Pat. No. 5,313,154, which describes an improved solution. However the inventors have performed a rigorous mathematical analysis of the problem of frequency comparison in a temperature-compensated resonant MEMS system. This has established that a different circuit architecture can achieve orders of magnitude improvement in low power jitter reduction as compared with previous approaches. That is, in embodiments, the mixer circuit should be responsive to a level which continues or extends over time rather than, for example, responding to a change or discontinuity or ‘edge’ in an oscillator signal. The benefit is frequency dependent but at frequencies of interest for MEMS devices using a level-sensitive mixer circuit which provides an output signal responsive to a level (an instantaneous level) of the oscillator outputs can reduce the phase error by an extraordinary close to 5 orders of magnitude

The benefit is greatest at lower frequencies (of the reference oscillator), for example less than 1 MHz or potentially less than 100 KHz. It is reduced at higher frequencies but is nonetheless still significant. The upper limit frequency for substantial benefit has not been established but is perhaps of order of 1 GHz. Preferably, therefore, embodiments of the invention are used at frequencies of less than 1 GHz, more preferably less than 100 MHz, most preferably less than 10 MHz. Similarly, although the described approach is particularly advantageous with square waves, and to simplify the analysis only square waves are considered later, it is expected that the benefit of the described approach is not limited to the use of square wave oscillators.

Embodiments of the above described system thus enable a temperature-compensated resonant MEMS system to achieve a very low noise/very high resolution whilst at the same time having a very low power consumption.

In some preferred embodiments of the system the low-pass filter is implemented using a transconductance amplifier having an output coupled to an output capacitance, the transconductance amplifier providing a current source sink for the output capacitance dependent upon a voltage level of the mixer output. This provides an especially low power implementation of the low pass filter. More particularly, in embodiments the current source/sink of the transconductance amplifier is arranged to be dependent on a bias current of the transconductance amplifier, and in this way a cut-off frequency of the low pass filter is arranged to be dependent upon this bias current. The bias current can be reduced concomitantly with the cut-off frequency, and thus the bias current can be reduced by reducing the dynamic range/bandwidth of the system (which relates to the cut-off frequency); this can also be used to reduce power. Preferably the cut-off frequency is selected to be less than a frequency of the difference frequency component described above.

Conveniently, but not essentially, where the sensor and reference oscillators provide square wave outputs the level sensitive mixer circuit may comprise an XOR or XNOR gate. Preferably in combination with this the oscillator circuits each comprise an amplifier with a respective resonant MEMS device in a feedback path. A MEMS device can be modelled as a series-connected resistor, inductor and capacitor, and with this type of oscillator circuit the device can be operated at a frequency where it appears inductive, using one or more capacitors to adjust to a total phase shift around the feedback loop of substantially zero. In preferred embodiments a square wave drive is applied to the MEMS device, preferably with close to a 50% (+/−20%, +/−10%, or +/−5%) duty cycle. This approach further facilitates achieving a very low power consumption, for example in embodiments an oscillator power consumption of less than 2 μW (C. Do, A. Erbes, J. Yan, and A. A. Seshia, “Low power MEMS oscillators for sensor applications”, in Proceedings of the 28th European Frequency and Time Forum (EFTF) conference, Neuchatel, Switzerland, Jun. 23-26, 2014.).

In some preferred embodiments of the system one or both of the resonant MEMS devices comprises a double-ended tuning fork (DETF). Embodiments of such a system can operate at very low power and provide a strain resolution of better than 1 nanostrain over a range of temperatures and with a very low noise floor. However applications of the techniques we describe are not limited to (single- or multi-axis) strain gauges and may be employed with other types of resonant MEMS sensors including, but not limited to, sensors measuring vibration, tilt, acceleration, pressure and acoustic emission. For example the techniques we describe may also be implemented in a resonant MEMS gyroscope—which may be based, for example, on a tuning fork, where a change in frequency depends upon the rotation rate of the gyro. Such a MEMS gyro may be used to determine an angular rate or attitude angle signal from the MEMS devices. In preferred embodiments of the system the first and second MEMS devices are fabricated on a common substrate; in the case of a tuning fork arrangement one may be at right angles to the other.

The system designs we have described are of sufficiently low power consumption that, in embodiments, a MEMS-based energy harvesting device may be provided, preferably on the same substrate as the other MEMS devices. This may be coupled to an energy harvesting (power conditioning) circuit for powering the system of circuit elements described above. One example MEMS-based harvesting device comprises a mechanical parametric oscillator for example of the type we have previously described in WO2013/175449.

Preferably the circuitry is implemented in CMOS. In embodiments the CMOS circuitry and MEMS devices may be provided within a single package, for example a ceramic package. Within such a package a stacked die configuration may be employed. Preferably, but not essentially, the MEMS devices are in a vacuum. In embodiments either or both of the CMOS circuitry and MEMS devices may be fabricated on a silicon-on-insulator (SOI) substrate.

In a related aspect the invention provides a method of jitter reduction in a MEMS system, the method comprising: inputting a first oscillator signal from a first resonant MEMS device; inputting a second oscillator signal from a first resonant MEMS device; mixing said first and second oscillator signals in a level-sensitive mixer circuit to generate a substantially jitter-free mixed signal output comprising sum and difference frequency components of said first and second oscillator signals; low-pass filtering said mixed signal output to attenuate said sum frequency component of said mixed signal output and provide a substantially jitter-free filtered signal output; and providing said filtered signal output, comprising said difference frequency, component for further processing.

In preferred implementations the low pass filtering uses a transconductance amplifier to provide a current source/sink to an output capacitance dependent upon a voltage level of the mixed signal output. Preferably the transconductance amplifier circuit is configured such that the current source/sink is dependent on a bias current of the transconductance amplifier such that a cut-off frequency of the low-pass filter is dependent upon the bias current and is less than a frequency of the difference frequency component. In embodiments the mixing uses an XOR or XNOR gate. Preferably the first and second resonant MEMS devices are driven with respective square waves with a duty cycle of 50%+/−10%, preferably at respective frequencies at which the devices appear substantially inductive.

### BRIEF DESCRIPTION OF THE DRAWINGS

These and other aspects of the invention will now be further described, by way of example only, with reference to the accompanying figures in which:

FIGS. 1a to 1c show, respectively, an example of a MEMS double-ended-tuning fork (DETF) device, an electrical view of the device, and an example of the device attached to a steel bar for use in monitoring a crack in the infrastructure such as a tunnel;

FIGS. 2a and 2b show, respectively, a block diagram of a temperature-compensated resonant MEMS system according to an embodiment of the invention, and example waveforms to illustrate operation of the system of FIG. 2a;

FIG. 3 shows a circuit diagram of an example CMOS transconductance capacitance low-pass filter for use in the system of FIG. 2a;

FIG. 4 shows a circuit diagram of an example CMOS Schmitt trigger for use in the circuit of FIG. 2a;

FIGS. 5a to 5c show, respectively, first and second examples of a MEMS oscillator for use in the system of FIG. 2a, and a MEMS oscillator including an automatic gain control (AGC) loop for use in embodiments of the invention;

FIGS. 6a to 6c show, respectively, an example implementation of the resonant MEMS system of FIG. 2a in a wireless strain gauge, an example of the system of FIG. 2a implemented in a resonant tuning fork-based gyroscope, and an example physical structure of a temperature-compensated strain gauge using dual-MEMS resonators;

FIGS. 7a to 7d show, respectively, first and second example edge-based frequency differencing circuits, example waveforms for the system of FIG. 2a illustrating output rising and falling edges, and an illustration of jitter in these rising and falling edges for use in a mathematical comparison of edge-based and level-based signal processing;

FIGS. 8a and 8b show graphs of phase error against frequency for edge-based (left) and level-based (right) signal processing, the latter according to the system of FIG. 2a, for a first device (f1) resonant frequency of 200 KHz and 20 MHz respectively with a bandwidth of |f2−f1|=40 KHz and with the phase noise in the level-based graphs shown at a standard deviation of σ=10 ps;

FIGS. 9a to 9e show example simulation results for the system of FIG. 2a illustrating (referring to FIG. 2a) f1, f2, A, B and fd for, respectively: f1=230 KHz, f2=200 KHz; f1=201 KHz, f2=200 KHz, f1=f2=200 KHz, initial phase=0 degrees; f1=f2=200 KHz, initial phase=90 degrees; and f1=f2=200 KHz, initial phase=70 degrees;

FIGS. 10a to 10d show, respectively, the interior of a ceramic package comprising CMOS circuitry and MEMS devices to implement the system of FIG. 2a, first and second close-up views of the CMOS circuitry, and a close-up view of the MEMS devices;

FIGS. 11a to 11c show, respectively, an Allan deviation plot for an example system of the type shown in FIG. 10 operating at an output frequency of fd=10.09 KHz; example output waveforms fd for f1=120 KHz, f2=120.1 KHz (left) and f1=120 KHz, f2=130 KHz (right) in other example systems; and a further example Allan deviation plot for a system with fd=1 KHz; and

FIGS. 12a to 12c show example Allan deviation plots for systems with, respectively, fd=40 KHz, fd=10 KHz, and fd=100 Hz.

### DETAILED DESCRIPTION OF PREFERRED EMBODIMENTS

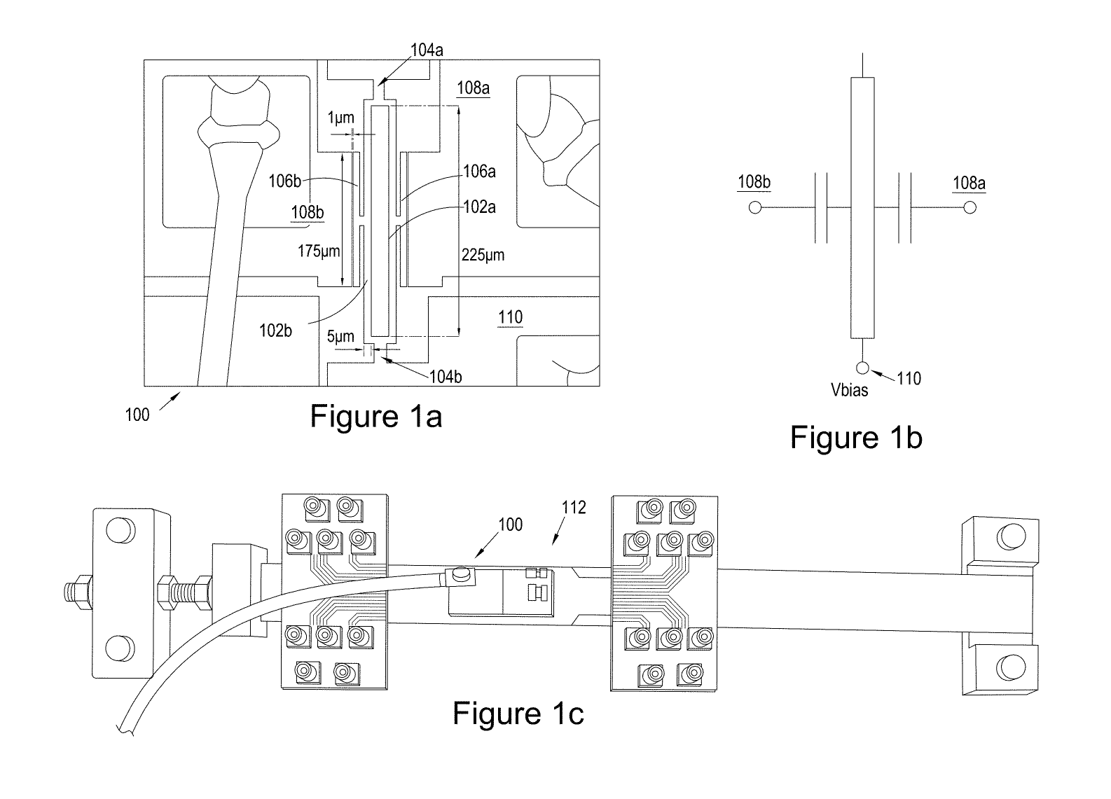

It is helpful for understanding the invention to consider the operation of an example resonant MEMS device. FIG. 1a shows an example double-ended tuning fork strain sensor 100 of a type which is preferably (but not essentially) vacuum packaged.

This example sensor has a pair of tines 102a, b fastened at each end 104a, b but free to vibrate in between. Each tine is attached to a respective driving electrode 106a, b, in the example a parallel-plate type driving electrode, although comb drive electrode arrangements may also be employed. The drive electrodes 106a, b are driven by respective counter electrodes 108a, b. Typically in electrostatically driven resonators a bias voltage is applied between the resonator body and a driving electrode; this may be provided by a bias voltage connection 110, although potentially this may be a ground connection.

A simplified electrical view of the DETF 100 is shown in FIG. 1b; as previously mentioned the equivalent circuit comprises series connected resistance, inductance and capacitance, although this is a simplistic view as, for example, a real device includes various parasitic capacitances. The DETF 100 exhibits a sharp mechanical resonance, and a correspondingly sharp (frequency-dependent) electrical transfer function between electrodes 108a, b.

A DETF MEMS device of the type shown in FIG. 1a has a number of applications, one of which is used as a strain gauge. When used as a strain gauge the tuning fork is bonded to a strained material so that the tuning fork is stretched with the material, changing its resonant frequency to enable detection/measurement of the strain. For example, as shown in FIG. 1c, the sensor 100 may be bonded with epoxy or the like to a (steel) bar 112, the ends of which may then be mechanically attached to either side of a crack or potential crack. In this way the MEMS sensor may be used for crack detection/monitoring in, for example, civil engineering infrastructure such as bridges, tunnels and the like.

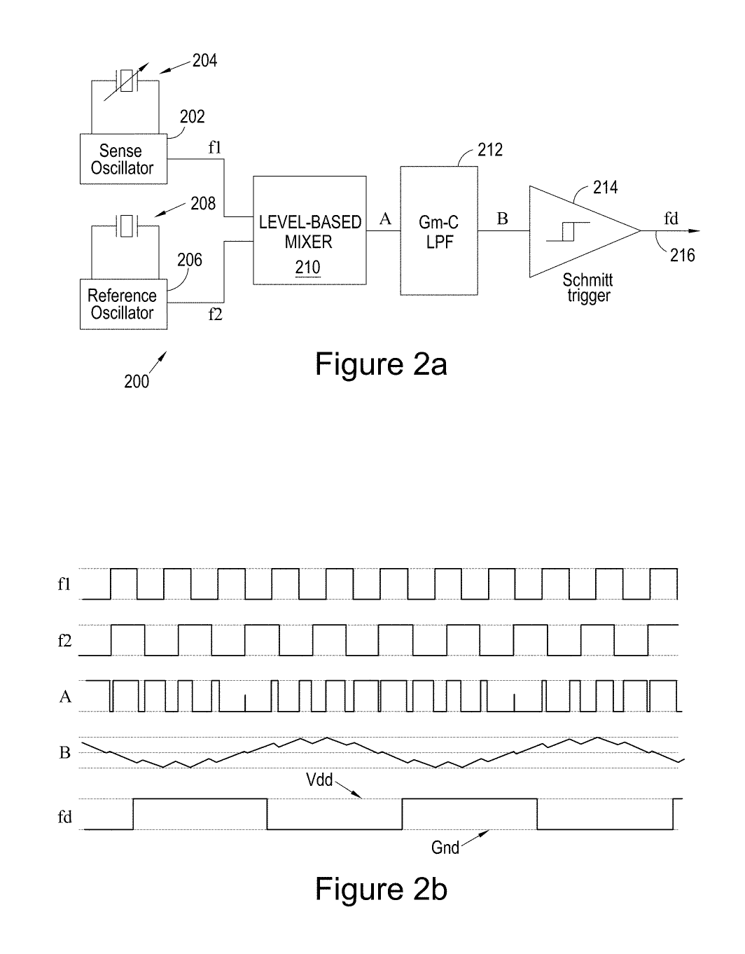

Referring now to FIG. 2a, this shows a block diagram of a temperature-compensated resonant MEMS system 200 according to an embodiment of the invention. Thus the system comprises a first sense oscillator circuit 202 comprising a first resonant MEMS device 204, operating at a first frequency f1, and a second oscillator circuit 206 comprising a second resonant MEMS device 208 and operating at a second frequency f2. The first MEMS device 204 is shown as a variable device and has a resonant frequency which is affected by a sensed parameter or ‘measurand’ (as well as being affected by temperature). The second MEMS device 208 is also responsive to temperature in substantially the same way as device 204, but is insensitive to the measurand.

The outputs of the first and second oscillators 202, 206 are provided to a level-sensitive mixer circuit 210. In preferred embodiments the oscillator outputs are square wave outputs and mixer 210 acts as a digital mixer. The output, ‘A’ of mixer 210 has two frequency components, a sum frequency component (f1+f2 or, equivalently, 2f+Δf), and a difference frequency component Δf=|f1−f2|. The output of mixer 210 is coupled to a transconductance-capacitance (Gm-C) low-pass filter 212, which attenuates the high frequency component leaving the difference frequency. The operation of these circuit blocks is described in more detail later. In preferred embodiments, however, the low-pass filter 212 is arranged so that the power dissipation can be reduced by reducing the cut-off frequency, thus facilitating an overall power reduction for the system. The output of the transconductance capacitance low-pass filter 212, ‘B’, provides an input to a Schmitt trigger 214, which conditions the signal prior to providing a difference frequency output, fd on line 216. This signal may be further processed by, for example, a frequency counter or by providing the signal as a (digital) input to a microprocessor/microcontroller (not shown). FIG. 2b shows example waveforms at the labelled points f1, f2, A, B and fd in FIG. 2a. These illustrate the operation of the circuit as described further below.

As previously described, in preferred embodiments the two frequencies f1 and f2 comprise digital signals and in one embodiment the level-sensitive mixer 210 is implemented as an XNOR gate. As the skilled person will know, the output of an XNOR gate is high if the two inputs are the same (both high, or both low) and the output is low if the two inputs are at different logic levels (one high, the other low).

As illustrated in FIGS. 2b, f1 and f2 are the two input signals to the XNOR gate; in the example of FIG. 2b frequency f1 is slightly higher than the frequency f2 input. The output of the XNOR gate is depicted as waveform A: The voltage of A is high whenever the voltages of both waveforms f1 and f2 are the same, if one but not both inputs is high, a low output results.

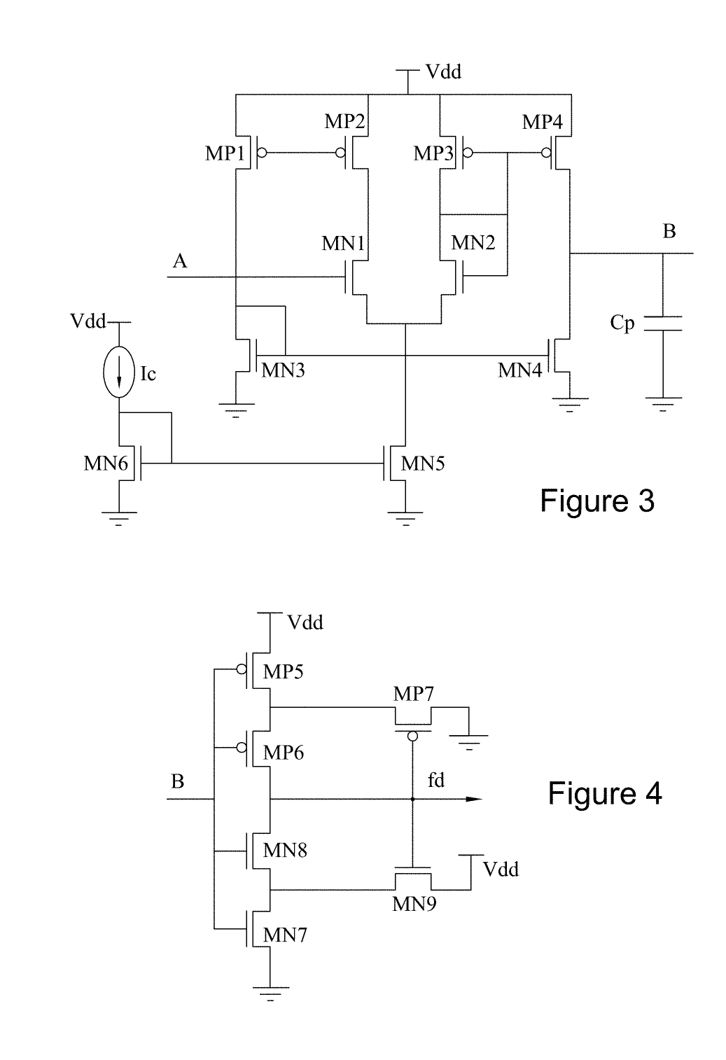

In the next stage the signal output of the XNOR gate, A, is fed into the Gm-C filter 212. A detailed circuit diagram of one preferred embodiment of the Gm-C filter is shown in FIG. 3. The Gm-C filter includes an Operational Transconductance Amplifier (OTA) with a capacitance Cp connected across the output; Vdd indicates the supply voltage.

In FIG. 3 the OTA translates an input voltage into an output current. Transistors MN1 and MN2 form a differential input stage. Transistors MP1-MP4 and MN3-MN4 form two self-biased current mirror circuits. The gate terminal of transistor MN2 is coupled to its drain in a feedback topology. The source terminals of transistors MN1 and MN2 are coupled to one another and to the drain of transistor MN5. The current on the transistor MN5 is mirrored from transistor MN6. The current in transistor MN6 is controlled by a current reference Ic, which therefore (indirectly) biases the differential input circuit. The cut-off frequency of the Gm-C filter is controlled by this Ic bias current. The lower the cut-off frequency of the filter, the smaller the bias current Ic is needed.

When the maximum deviation frequency between the two input frequencies is known the minimum Ic bias for that frequency is chosen to minimize power consumption of the circuit. For example at a maximum frequency difference of 40 kHz the bias current Ic can be set at around 100 nA without affecting the operation of the circuit.

As described previously, the signal input, A, of the Gm-C filter shown in FIG. 3 is from the output of the XNOR gate. The digital waveform at point A is shown in FIG. 2. The circuit FIG. 3 operates as follows:

When the input voltage at point A is high, transistor MN1 is open (on). The current at the drain of transistor MN1 is limited due to the biased current of transistor MN5. This pulls the drain voltage of transistor MN1 down. As the drain of transistor MN1 is coupled to the gate of transistor MP2, more current is drawn through the transistor MP2 until it carries the same current as transistor MN1. The current of MP2 is mirrored to the current of transistor MP1. Due to the series connection of MP1 and MN3, the current through transistor MN3 is the same as the current through the transistor MP1. Again, the current of transistor MN4 mirrors the current of transistor MN3. This mirror (MN4) current sinks current from the output (filter) capacitor Cp. On the other side of the circuit, as transistors MN1 and MN2 are differentially coupled and the gate of the transistor MN2 is coupled to its (own) drain to implement a feedback structure, the transistor MN2 is off when the input voltage, A, is high. As there is no current through the transistor MN2, no current flows through transistor MP3 and the mirrored transistor MP4. Therefore, no current from transistor MP4 is provided to the output capacitance Cp. In short, when the input voltage, A, is high a current which is equivalent to the bias current Ic is sunk from the output capacitance Cp.

When the input voltage at point A is low, the transistor MN1 is off and no current flows through it. The current of the series connected transistor MP2 is accordingly zero, as is to the mirrored current of transistor MP1. Consequently, no current flows through transistor MN3 and its mirrored transistor MN4. Therefore, no current is sunk from the output capacitance Cp by the transistor MN4. On the other side of the circuit, in a similar way to that described in the preceding paragraph, all the current sunk by transistor MN5 is now drawn from (only) transistor MN2. Consequently, the mirrored current from transistor MP4 provides a current to the output capacitance Cp. In short, when the input voltage, A, is low, a current which is equivalent to the bias current Ic is provided (sourced) into the output capacitance Cp.

In general the output voltage at point B increases at a constant rate if the input voltage, A, is maintained low, and decreases at the same constant rate if the input voltage, A, is maintained high. The waveform B in FIG. 2 demonstrates the output of the Gm-C filter guide the input waveform A. It can be seen that the circuit shown in FIG. 3 acts as a low pass filter: The high frequency portion of waveform A is filtered out. The low frequency portion, which is equivalent to the difference in frequency between f1 and f2, is retained at the output as waveform B. However as can be seen, the signal waveform of B still has spikes at higher frequencies. A Schmitt trigger is therefore employed in the subsequent stage to extract the desired, low frequency part of waveform B.

FIG. 4 shows an example circuit for the Schmitt trigger 216 of FIG. 2a. The Schmitt trigger is designed to provide hysteresis. When the output, fd, is high and the input exceeds a value of V_{H}=0.75*Vdd, the output switches to low. From this point, the input voltage must go below V_{L}=0.25*Vdd before the output can switch high again. The values of V_{H} and V_{L} are selected to suppress the spikes appearing on waveform B, and in embodiments can achieve this even when the difference frequency between f1 and f2 is reduced to as low as one cycle per second. V_{H} and V_{L} are selected by sizing the ratios of transistors MN7-MN9 and MP5-MP7. Thus in preferred embodiments the output waveform fd is a digital signal; its frequency is the difference frequency between the two input signals f1 and f2.

The difference frequency between the two input frequencies should be lower than the designed cut-off frequency (3 dB point) of the Gm-C filter. The frequency of both signal inputs (f1, f2) should be higher than the designed cut-off frequency (3 dB point) of the Gm-C filter.

As we will explain further below, in embodiments of this system the output signal is not susceptible to jitter. The power consumption may also be very low, for example of 480 nA average at Vdd=1.2 V and with a 40 kHz cut-off frequency (for example f1=200 kHz, f2=160 kHz). This power consumption may be reduced still further if the cut-off frequency is reduced. The CMOS power supply voltage is preferably less than 5V. In one example device a DC bias voltage of 18V was employed as the polarisation voltage for both resonators (to facilitate transduction of the motional signal), but this can be reduced by increasing the transduction area, reducing the pressure in the package to reduce viscous damping, and the like.

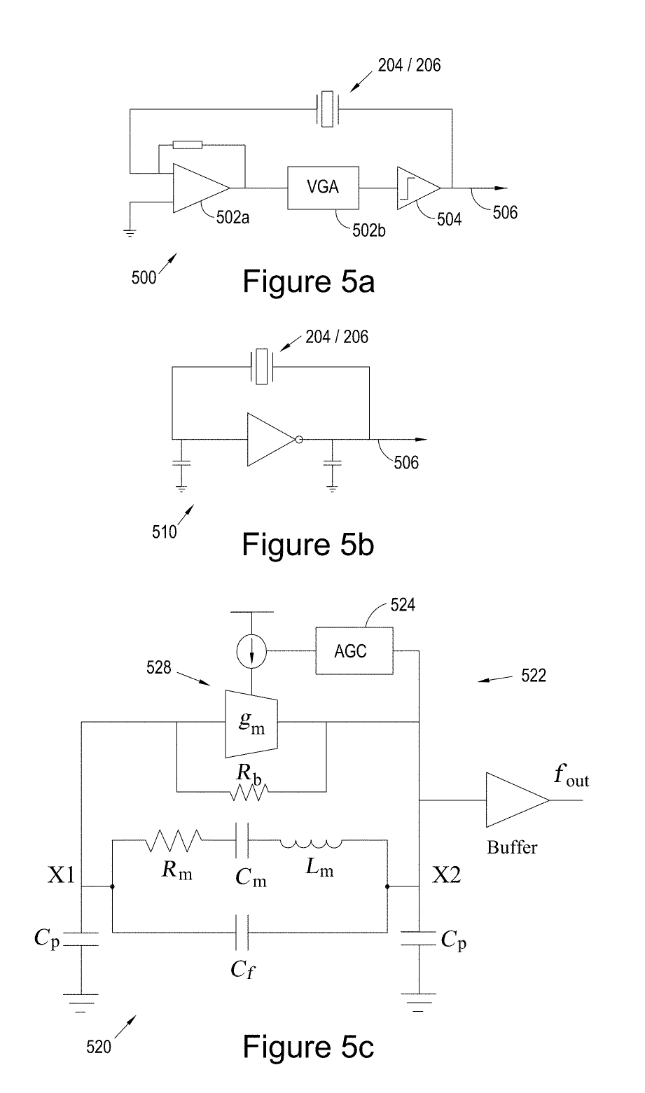

FIG. 5a shows an example oscillator circuit 500 for use with the system of FIG. 2a. In this circuit the MEMS device 204/206 is connected in series with a feedback path of an amplifier 502 and a hard or soft limiter 504, to provide an output 506. In the illustrated example amplifier 502 comprises an operational amplifier 502a and a variable gain amplifier 502b. FIG. 5b shows an alternative, Pierce-type oscillator 510 which may also be employed. Both oscillators provide a square wave drive to the MEMS device and exhibit low noise and low power consumption.

FIG. 5c shows a block diagram of one preferred implementation of an oscillator 520, in the example a Pierce oscillator, which includes an AGC (automatic gain control) circuit 522 in the feedback loop. The AGC circuit preferably comprises an AGC control block 524 coupled to a controllable transconductance element (gₘ) 526. This helps to minimise the power consumption, in particular by controlling the transconductance to target the critical point of the oscillator. An AGC circuit also helps to prevent driving the MEMS resonator into a non-linear regime. An oscillator of the type shown in FIG. 5c can thus be reliably operated at 1 pA with a 1.2V supply. In FIG. 5c the resonator is shown as an electrical equivalent circuit which, in an example embodiment had values Cp=3 pF, Rm=800KΩ, Cm=198 aF, Lm=3.85 kH, Cf=400 fF; in one embodiment the resonant frequency was ˜182 Khz, with Q=6100.

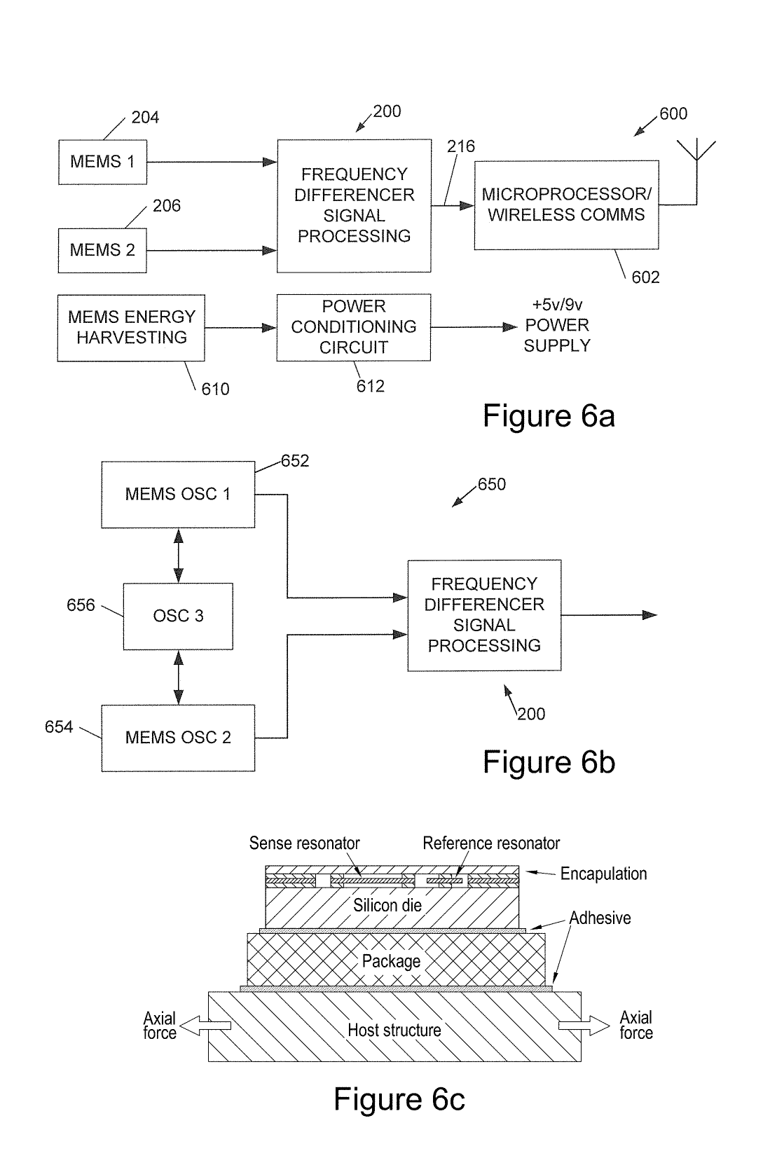

FIG. 6a shows an example of an energy-harvesting wireless sensor 600 employing a temperature-compensated resonant MEMS system 200 as previously described. MEMS system 200 provides a digital output at fd, to a digital input of a wireless communications module 602, optionally in combination with a microprocessor/microcontroller. The system also includes a MEMS energy harvesting device 610. This is preferably on the same substrate as devices 204, 206 and coupled to a suitable power conditioning circuit 612, to provide a power supply at one or more voltages to MEMS system 200. The power conditioning circuit may comprise, for example, storage (such as a capacitor), rectification, and a DC/DC voltage boost circuit.

FIG. 6b shows, schematically, an example application of the resonant MEMS system 200 of FIG. 2a in a tuning-fork based resonant output gyroscope 650. The relevant part of the system is very similar to that described previously except that, in this example, the tuning fork based MEMS oscillators 652, 654 are coupled to a shared third oscillator 656 whose motion is modulated by the Coriolis effect. The difference in frequency between the two MEMS oscillators can be used as a measure of rotation of the gyroscope, more particularly to determine an angular rate or attitude angle signal, in a manner with which the skilled person will be familiar.

### Temperature Compensation

In a strain gauge application, a silicon structure may be bonded onto the package using an adhesive, and the package may, in turn, be bonded to the monitored structure. An example is shown in FIG. 6c. Then a change in temperature not only affects the elasticity of the resonator structure (the temperature coefficient of frequency, TCF, is of order −30 ppm/° C.), but the thermal expansion (or contraction) of the die, package, carrier and adhesive layer also contributes to axial stress on the resonator. In preferred embodiments the sense and reference resonators are perpendicular to one another, to reduce the sensitivity of the reference to the applied strain.

Resonant frequencies of the sense, f_{S}, and reference, f_{R}, resonators can be expressed as:

f_{S}=f_{0S}+α₁ε+(TCF_{Si-S}+β_{S})ΔTf_{0S}

f_{R}=f_{0R}+α₁ε+(TCF_{Si-R}+β_{R})ΔTf_{0R}

where f_{0S} and f_{0R} are the resonant frequencies of the two resonators for zero load at a particular temperature, ε is the strain induced on the attached sensor due to the mechanical deformation of the host structure to be monitored, α1 is the strain-frequency coefficient of the Sense resonator with strain on, and α2 is the strain-frequency coefficient of the Reference resonator. TCF_{Si-S} and TCF_{Si-R} are temperature coefficients of frequency of silicon material on two resonators, and β_{S} and β_{R} are thermal stress induced coefficients of several layers (including host structure, package, silicon die, adhesives) for the two resonators.

In practice, the resonant frequency of the two resonators can be matched (f_{0S}=f_{0R}) through design, post-fabrication and/or circuit level trimming. Silicon is an anisotropic material; however preferably the directions of the two resonators are in the same crystal orientation (for example {100}) for the wafer orientation adopted in this process. Therefore, the TCF factors are expected to be substantially identical, that is TCF_{Si-S}=TCF_{Si-R}. As a result, by measuring the differential frequency between f_{S} and f_{R}, the TCF_{Si} factor may be cancelled. Thus the differential frequency is given by:

f_{d}=(β_{S}−β_{R})ΔT+(α₁−α₂)ε

Furthermore, β_{S} and β_{R} may be matched, for example if isotropic materials are used for the adhesive, carrier and host structure. Consequently, the differential frequency can then be substantially fully temperature compensated and expressed as:

f_{d}=(α₁−α₂)ε

The skilled person will recognise that such an approach is preferable, but not essential.

### Justification of Level-Based Signal Processing

We now describe the underlying mathematical justification for the orders of magnitude improvement in phase error achievable by the level-based signal processing methods we have described. We therefore provide a comparative analysis of the phase error in edge-based and level-based methods for a frequency deviation detector of a resonant MEMS system, the level-based approach analysed being that implemented using a system of the type illustrated in FIG. 2a. We first consider an edge-based method and then a level-based method.

### Phase Error of Edge-Based Methods

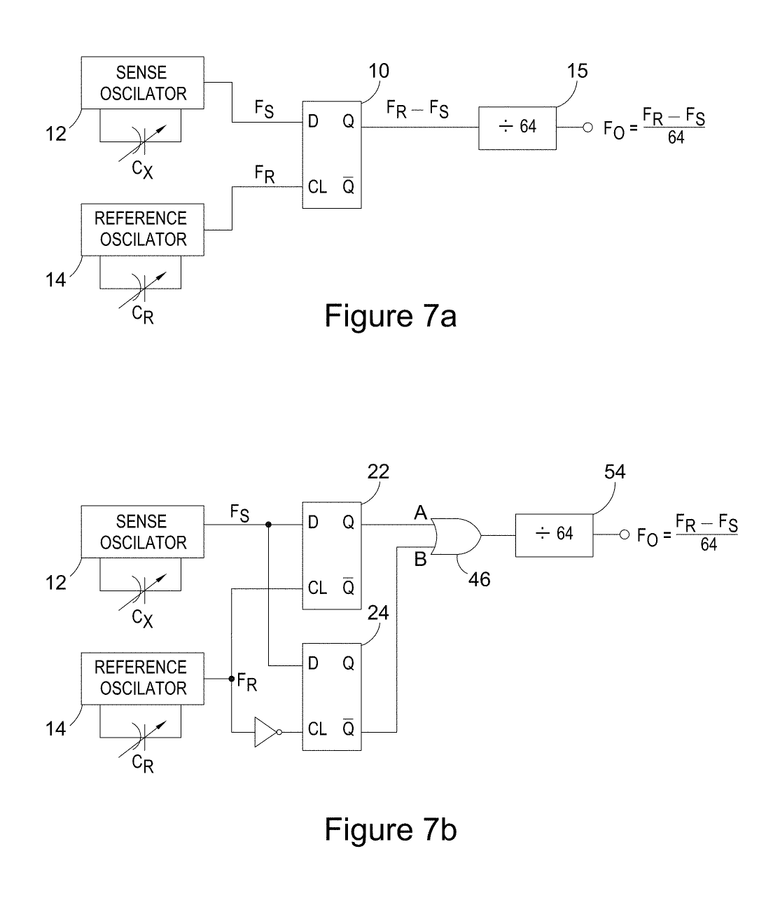

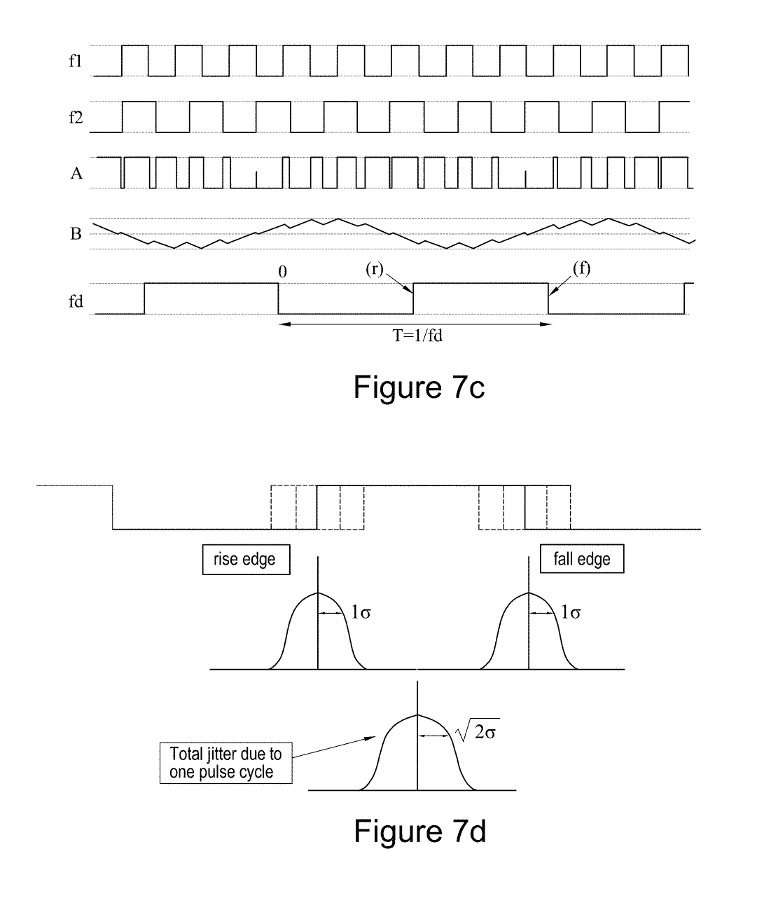

By way of example we analyse the edge-based systems described in U.S. Pat. No. 4,683,437, which employ D-type flip flops to generate an output signal indicative of the difference between the frequencies of two input signals. Two example circuits from U.S. Pat. No. 4,683,437 are shown in FIGS. 7a and 7b, one with one flip flop and a second with two flip flops. In both cases the latching output of a flip flop is based on the edges of the clock inputs and the circuits are therefore edge-based. In both circuits, however, the output transition edge may be shifted when two edge input transitions are clocked about the same time, for one period of the input signal where one D-type flip flop is used, and for half a period where two D-type flip flops are employed. This makes the circuits susceptible to jitter.

In more detail, consider two input frequencies, f1 and f2, that are applied to the edge-based systems of FIGS. 7a and 7b, with output frequency fout=|f1−f2|. In the circuit of FIG. 7a, where one D-type flip flop is used, the time error when jitter occurs is Δt=1/F_{R} and the phase error in degrees is:

$${φ}_{err\_ 1} = \frac{Δ t}{T} 360 = \frac{1 / {F}_{R}}{1 / \vert {F}_{R} - {F}_{S} \vert} 360 = \frac{\vert {F}_{R} - {F}_{S} \vert}{{F}_{R}} 360 ( degrees ) \qquad ( 1 )$$

In the circuit of FIG. 7b, where two D-type flip flops are employed, the time error is reduced by 2. The phase error in this case is halved and is thus:

$${φ}_{err\_ 2} = \frac{1}{2} \frac{\vert {F}_{R} - {F}_{S} \vert}{{F}_{R}} 360 ( degrees ) \qquad ( 2 )$$

### Phase Error of Level-Based Methods

Jitter is a deviation from the expected periodicity of a signal. Jitter is random may arise due to several factors, such as process variations, supply noise, intrinsic noise and thermal noise. Random jitter typically follows a Gaussian distribution or normal distribution N(μ,σ²). The mean of the distribution μ is typically 0 and the standard deviation, σ, depends on the design of the system and noise level.

We will analyse, in particular, the example level-based circuit of FIG. 2a, including the transconductance capacitance low pass filter (Gm-C LPF) and Schmitt trigger. We assume that the Gm-C LPF, which filters out the high frequencies and translates voltage level to current, operates in an ideal manner. Thus the jitters in the two digital blocks, the XNOR gate and the Schmitt trigger, therefore need to be considered. Referring to FIG. 7c, which shows example waveforms in the system, the evaluation is based on the phase error in one cycle of output fd.

The XNOR (or XOR) generates a pulse (A) in response to the levels of the two inputs f1, f2. Jitter occurs on both the rising-edge (r) and falling-edge (f) of the pulse. As jitter occurs randomly and independently on the rising-edge and falling-edge, the sum of the jitter on both these edges also has normal distribution with a standard deviation of \sqrt{2}σ. This is illustrated in FIG. 7d, which shows the total jitter in one cycle due to jitter on both the rising and falling-edges of pulse A.

The number of pulses of waveform A for one period cycle T=1/fd at the output fd (FIG. 7c) can be calculated as:

$$n = \frac{f 1 + f 2}{fd} = \frac{f 1 + f 2}{\vert f 1 - f 2 \vert} \qquad ( 3 )$$

It can therefore be seen that there are n/2 pulses in waveform A that contribute to the rising edge, (r) of the output fd. Because we have assumed that the jitter on every pulse is random and independent, the accumulated jitter error of the rising-edge is the sum of n/2 pulses on waveform A, each pulse having a jitter error as shown in FIG. 7d. The standard deviation of the accumulated jitter on the rising-edges (r) is \sqrt{n}σ, with a normal distribution N(0,nσ²).

The jitter on the falling edges (f) is the same as that on the rising edges, also, with a normal distribution N(0,nσ²). The total jitter in one full cycle of fd is the sum of jitter on both rising-edge and falling-edge has a normal distribution N(0,2nσ²). The standard deviation of the total jitter is \sqrt{2n}σ.

The Schmitt trigger can be considered as a comparator with digital output, and this intrinsically exhibits jitter, as illustrated by FIG. 7d. Therefore this circuit element also contributes to the total jitter of the output waveform fd. Assuming that the standard deviation of the jitter contributed by the XNOR circuit is σ, the overall accumulated jitter of both XNOR and Schmitt trigger is now characterised by N(0,2(n+1)σ²). Thus the total standard deviation is σₜ=\sqrt{2(n+1)}σ, that is the root mean square (rms) or average jitter is σₜ. The confidence interval is 68.2% for a number of jitters smaller than 1σₜ(second), and 99.7% of jitters are less than 3σₜ (second). Following this approach, the standard deviation phase error of the level-based system of FIG. 2a is found to be given by:

$${φ}_{err\_ 3} = \frac{{σ}_{t}}{T} 360 = \frac{\sqrt{2 ( \frac{f 1 + f 2}{\vert f 1 - f 2 \vert} + 1 )} σ}{1 / \vert f 1 - f 2 \vert} 360 = 360 \vert f 1 - f 2 \vert \sqrt{2 ( \frac{f 1 + f 2}{\vert f 1 - f 2 \vert} + 1 )} σ ( degrees ) \qquad ( 4 )$$

### Comparison of Edge-Based and Level-Based MEMS Signal Processing Methods

The phase error in equation (4) depends on the noise level in the system. For the systems we are considering the standard deviation of the jitter noise is usually in the range of a few picoseconds up to tens of picoseconds. In the analysis below we therefore assume a standard deviation σ=10 ps.

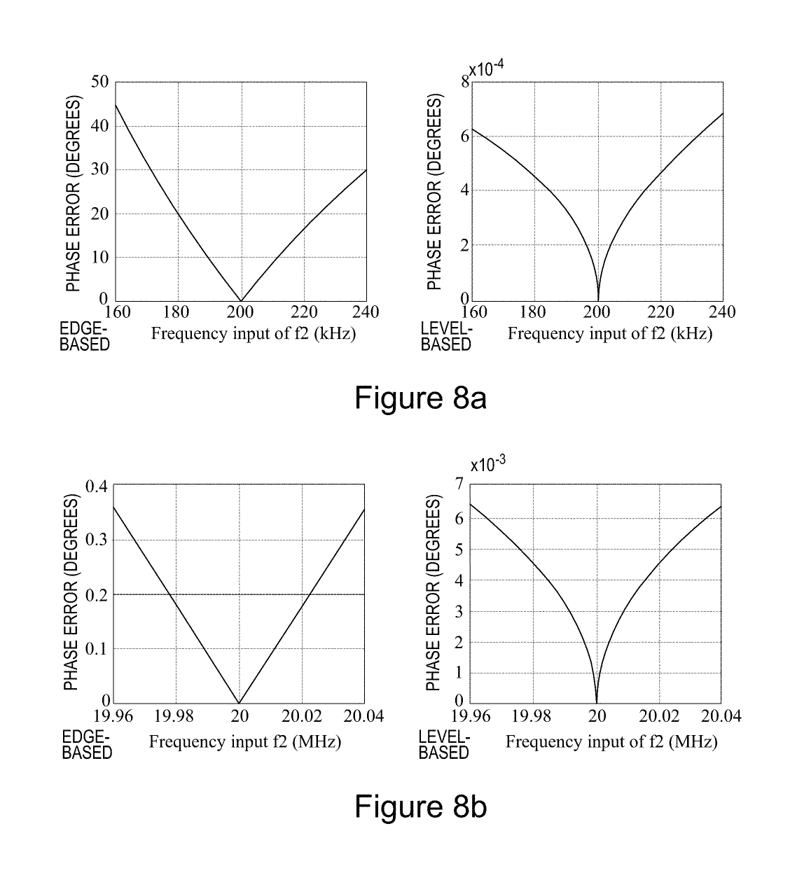

FIG. 8a shows the calculated phase errors of edge-based and level-based MEMS signal processing methods analysed using equations (2) and (4) above. It can be seen from FIG. 8a that the phase error in the level-based approach of FIG. 2a is reduced by almost by 5 orders of magnitude as compared with an edge-based approach, for a case where f1=200 kHz and f2 ranges from 160 kHz to 240 kHz. For both approaches phase errors increase as the frequency differences are increased.

FIG. 8b shows that at a higher frequency input (f1=20 MHz) the phase error of an edge-based approach is reduced as compared with f1=200 kHz whereas phase error of the level-based approach of FIG. 2a increases. However the difference between the two approaches is still around two orders of magnitude, showing the substantial advantage of using a level-based approach for reducing phase error in a resonant MEMS signal processing system. In typical sensor applications the frequencies employed are generally up to a few MHz, and thus the level-based system of FIG. 2a can provide substantial unexpected advantages in reducing phase error in the output signal.

### Simulation Results

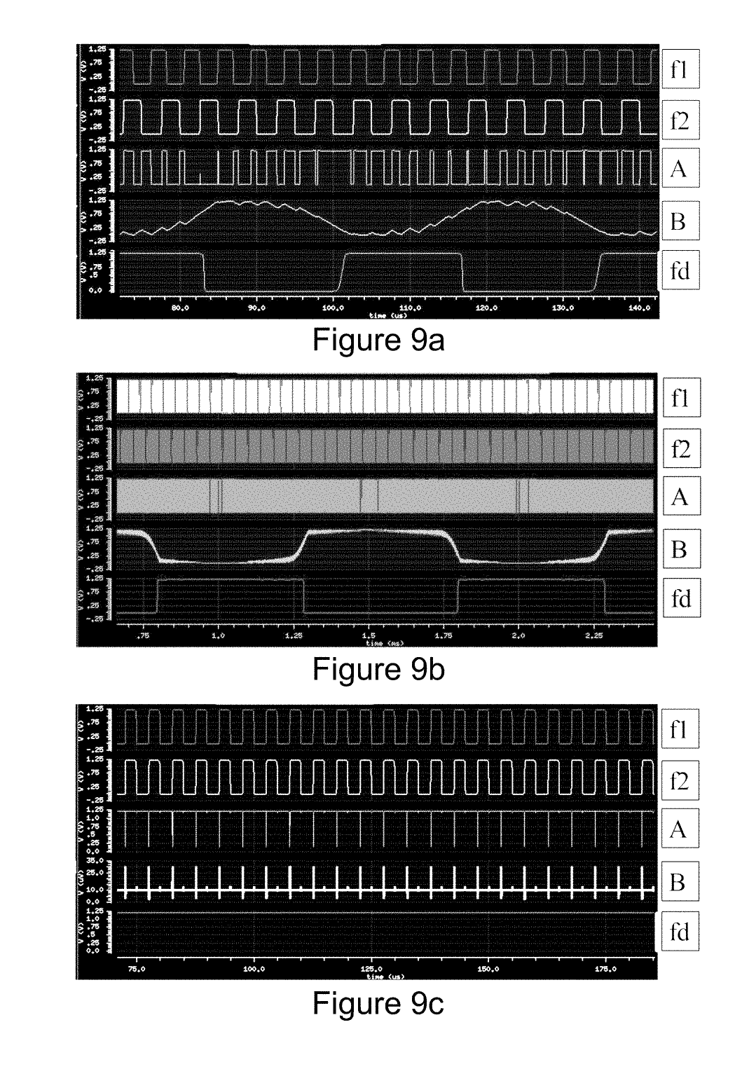

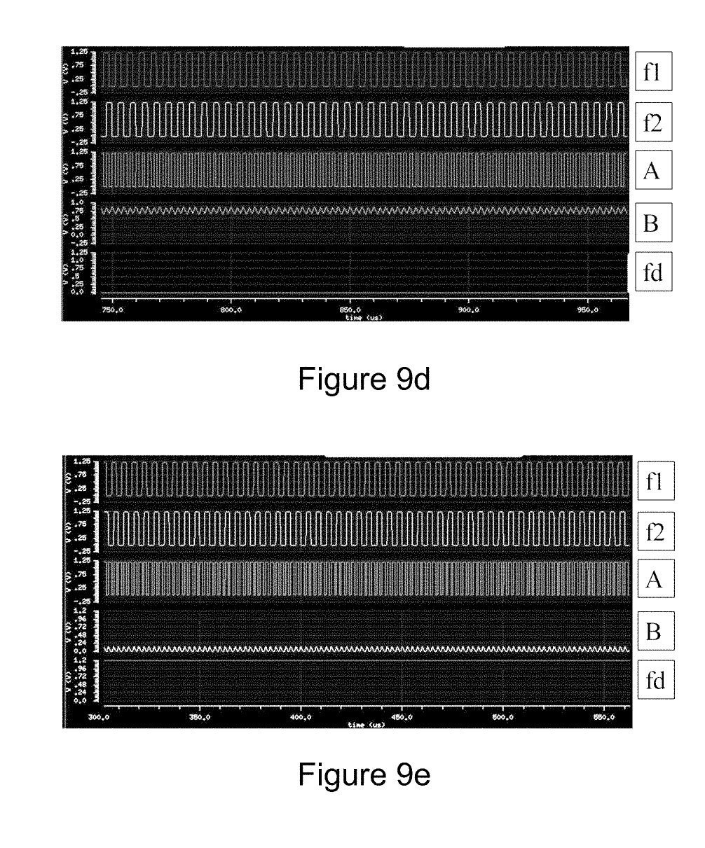

Example simulation results for the system of FIG. 2a are shown in FIG. 9. This illustrates the operation of a system designed for a cut-off frequency of the Gm-C filter of around 40 KHz, with a bias current Ic of 100 nA.

Referring to FIG. 9a, with f1=230 kHz and f2=200 kHz the output frequency, fd, is 30 kHz as expected. As the frequency difference becomes smaller, the waveform at point B becomes noisy but when f1=201 kHz, f2=200 kHz (FIG. 9b) the output of the Schmitt trigger still shows a very clear square waveform at a frequency of 1 kHz. In FIG. 9c both frequency inputs are the same (200 kHz) and in phase but although the signals at points A and B have some jitter this does not affect the output of the Schmitt trigger. FIG. 9d shows a similar case where the inputs are 90° out of phase. Here the duty cycle of signal A is 50% and equal currents flow into and out of capacitance Cp over every cycle, and hence the output fd is substantially constant. FIG. 9e shows a case where the inputs are 70° out of phase. Here the duty cycle of signal A is different to 50% but nonetheless the frequency of waveform A is constant at 2*f1, which is filtered out by the low-pass filter so that again the output fd is substantially constant.

### Example Systems

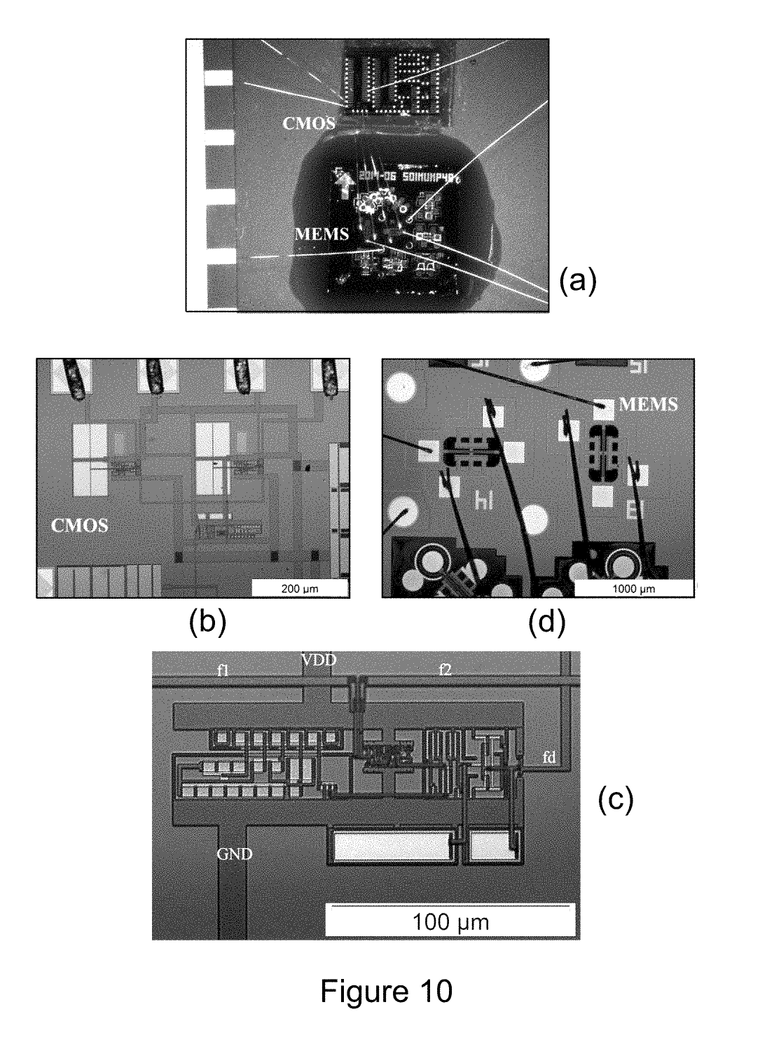

Referring to FIG. 10, this shows in FIG. 10a an example of a MEMS system comprising a double-ended tuning fork (DETF) strain sensor in combination with 0.35 μm CMOS circuitry (FIG. 10b) to implement the approach in FIG. 2a. FIG. 10c shows an enlargement of the highlighted region shown in FIG. 10b, which contains the circuitry of FIGS. 2a, 3 and 4. FIG. 10d illustrates the use of two MEMS resonators arranged to be orthogonal to one another, one for the strain sensor, the other as a reference.

In the example fabricated system of FIG. 10 the resonant frequency was approximately 80 KHz, the CMOS circuitry had a VDD supply voltage of 1.2 volts, and a 9 volt bias was used for the MEMS resonators. The total power consumption was around 1 μW (without loading at fd).

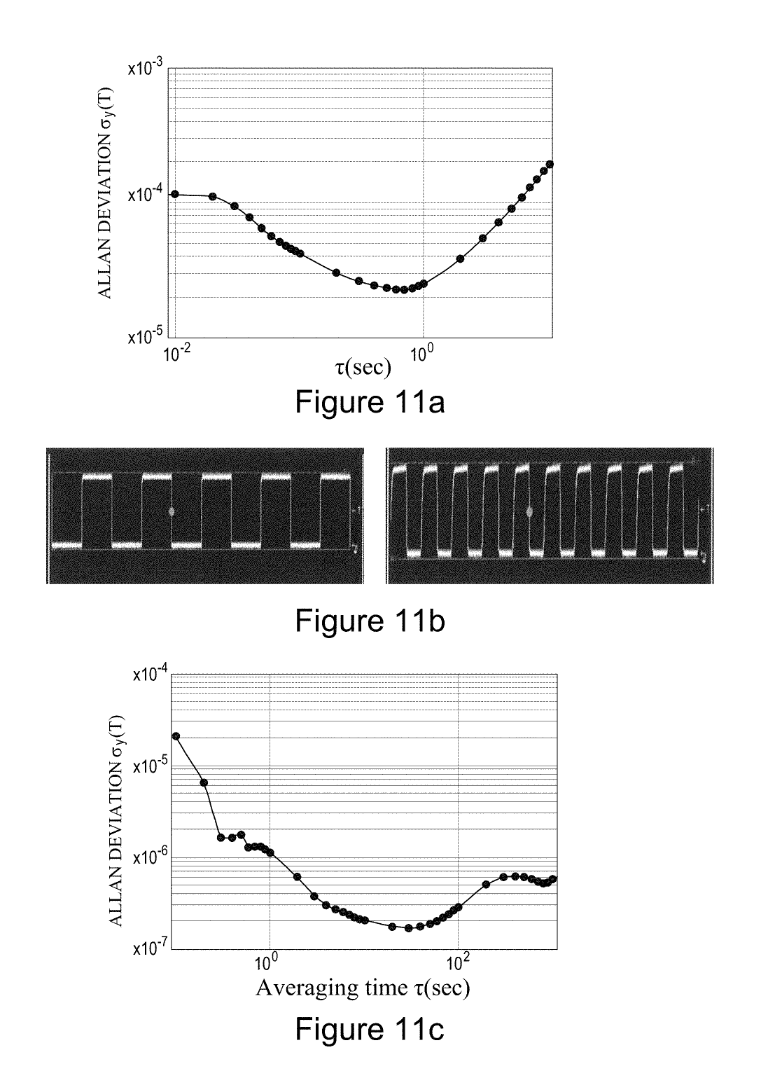

FIG. 11a shows a graph of the Allan deviation of fd for the system of FIG. 10 at an output frequency of fd=10.09 KHz. As the skilled person will be aware, broadly speaking the Allan deviation is the square root of the Allan variance, which is a measure of the variance of the differences between successive averages of the measured value (fd); averaging time is plotted on the x-axis and the Allan deviation on a log scale on the y-axis.

For comparison, FIG. 11b shows example output waveforms (fd) for a second example system with fd=100 Hz (left) and fd=10 Kz (right). In this example the duty cycle was 50%+/−5% over the design frequency range. The corresponding Allan deviation is shown in FIG. 11c for fd=1 KHz. This example system was designed with a cut-off frequency of 40 KHz for resonant MEMS frequencies in the range 100-300 KHz. The CMOS circuitry drew 400 nA from 1.2 volts supply, and no jitter was recorded in the output fd signal up to 38 KHz.

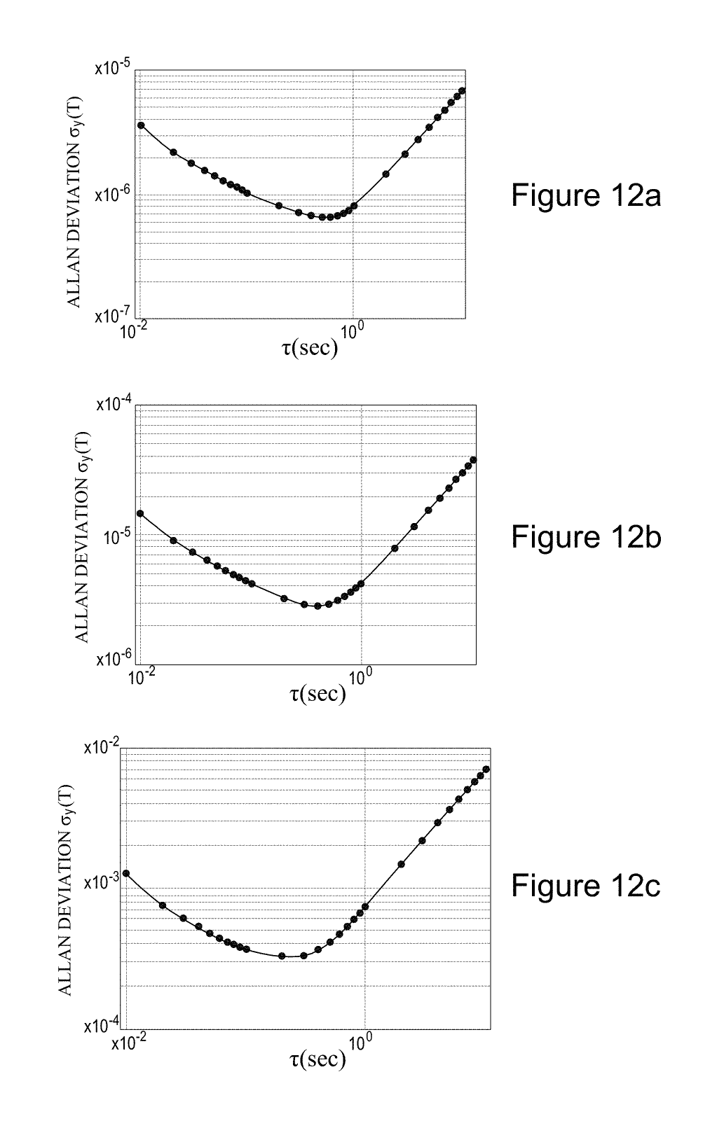

Referring again to the example of FIG. 10, FIGS. 12a to 12c show Allan deviation plots for this example system as fd decreases, from 40 KHz, to 10 KHz to 100 Hz respectively. The Allan deviation reduces as fd decreases, but at the best point the error is around 25-30 mHz, which is equivalent to that of the reference MEMS oscillator. The reference oscillator operated at 125 KHz; again no jitter was seen in the fd output. The power consumption varied slightly, with fd between around 500 nA and 700 nA. For such strain sensors near perfect temperature compensation can be achieved in the range 20-35° C.

As previously mentioned, in one example application a device as described herein is self-powered and includes a battery/energy storage capacitor and/or an energy harvesting device, such as a (piezoelectric) MEMS resonator. Preferably the MEMS MEMS sensor is a MEMS strain sensor. The very low power requirements of the techniques facilitate such a device which, in embodiments, may be a wireless sensor device, for example for structural health/infrastructure monitoring where a low continuous power dissipation is important.

No doubt many other effective alternatives will occur to the skilled person. It will be understood that the invention is not limited to the described embodiments and encompasses modifications apparent to those skilled in the art lying within the spirit and scope of the claims appended hereto.

1. A temperature-compensated resonant MEMS device, comprising:
a first oscillator circuit comprising a first resonant MEMS device and providing a first oscillator output;
a second oscillator circuit comprising a second resonant MEMS device and providing a second oscillator output;
wherein one of said first and second resonant MEMS devices is a temperature reference for the other of said first and second resonant MEMS devices;
a level-sensitive mixer circuit having first and second inputs respectively coupled to said first and second oscillator outputs and having a mixer output to provide a signal responsive to a level of said first and second oscillator outputs, said mixer output comprising sum and difference frequency components of said first and second oscillator outputs;
a low-pass filter coupled to said mixer output to attenuate said sum frequency component of said mixer output; and
an output coupled to an output of said low-pass filter to provide a signal responsive to said difference frequency component.

2. A temperature-compensated resonant MEMS device as claimed in claim 1 wherein said low-pass filter comprises a transconductance amplifier, wherein said transconductance amplifier has an output coupled to an output capacitance and provides a current source/sink to said output capacitance dependent upon a voltage level of said mixer output.

3. A temperature-compensated resonant MEMS device as claimed in claim 2 wherein said current source/sink of said transconductance amplifier is dependent on a bias current of said transconductance amplifier such that a cut-off frequency of said low-pass filter is dependent upon said bias current, and wherein said cut-off frequency is less than a frequency of said difference frequency component.

4. A temperature-compensated resonant MEMS device as claimed in claim 1 wherein said first and second oscillator outputs comprise square or rectangular wave outputs, and wherein said mixer comprises an XOR or XNOR gate.

5. A temperature-compensated resonant MEMS device as claimed in claim 4 wherein said first and second oscillator circuits comprise respective first and second amplifiers and wherein said first and second resonant MEMS devices are in respective feedback paths of said first and second amplifiers.

6. A temperature-compensated resonant MEMS device as claimed in claim 1 wherein said first resonant MEMS device comprises a strain gauge, in particular a double-ended tuning fork.

7. A temperature-compensated resonant MEMS device as claimed in claim 1 wherein said first and second MEMS devices comprises coupled oscillators of a resonant MEMS gyro.

8. A temperature-compensated resonant MEMS device as claimed in claim 1, wherein said first and second MEMS devices are fabricated on a common substrate.

9. A temperature-compensated resonant MEMS device as claimed in claim 8 further comprising a MEMS-based energy harvesting device coupled to an energy harvesting circuit, and wherein said first and second oscillator circuits, said mixer circuit and said low-pass filter are powered by said energy harvesting circuit.

10. A temperature-compensated resonant MEMS device as claimed in claim 9 wherein said MEMS-based energy harvesting device comprises a mechanical parametric oscillator, in particular fabricated on said common substrate.

11. A method of jitter reduction in a MEMS system, the method comprising:
inputting a first oscillator signal from a first resonant MEMS device;
inputting a second oscillator signal from a first resonant MEMS device;
mixing said first and second oscillator signals in a level-sensitive mixer circuit to generate a substantially jitter-free mixed signal output comprising sum and difference frequency components of said first and second oscillator signals;
low-pass filtering said mixed signal output to attenuate said sum frequency component of said mixed signal output and provide a substantially jitter-free filtered signal output; and
providing said filtered signal output, comprising said difference frequency, component for further processing.

12. A method as claimed in claim 11 wherein said low pass filtering comprises using a transconductance amplifier to provides a current source/sink to an output capacitance dependent upon a voltage level of said mixed signal output.

13. A method as claimed in claim 11 further comprising controlling said current source/sink dependent on a bias current of said transconductance amplifier such that a cut-off frequency of said low-pass filter is dependent upon said bias current, and wherein said cut-off frequency is less than a frequency of said difference frequency component.

14. A method as claimed in claim 11, wherein said mixing comprises providing said first and second oscillator signals to an XOR or XNOR gate.

15. A method as claimed in claim 11 further comprising driving said first and second resonant MEMS devices with respective square waves with a duty cycle of 50%+/−10%.

16. A method as claimed in claim 15 further comprising driving said first and second resonant MEMS devices at respective frequencies at which the MEMS devices appear substantially inductive.

17. A method as claimed in claim 11 further comprising using a further MEMS device for energy harvesting to power the first and second resonant MEMS devices, said mixing, and said low-pass filtering.

18. A method as claimed in claim 11 further comprising using one of said first and second resonant MEMS devices to provide temperature compensation for the other of said first and second resonant MEMS devices.

19. A method as claimed in claim 11 further comprising using said filtered signal output to determine a strain signal; and wherein said first and second resonant MEMS devices comprise double-ended tuning forks.

20. A method as claimed in claim 11 further comprising using said filtered signal output to determine an angular rate or attitude angle signal; and wherein said first and second resonant MEMS devices comprise of devices a resonant MEMS gyroscope.
